(19) United States
(12) Patent Application Publication
(10) Pub. No.: US 2012/0104939 A1
(43) Pub. Date: May 3, 2012

(54) ORGANIC LIGHT EMITTING DISPLAY DEVICE

(75) Inventors: Yong-Sung Park, Yongin-city (KR); Wang-Jo Lee, Yongin-city (KR); Ki-Nyeng Kang, Yongin-city (KR); Ki-Wook Kim, Yongin-city (KR)

(73) Assignee: Samsung Mobile Display Co., Ltd., Yongin-city (KR)

(21) Appl. No.: 13/177,452

(22) Filed: Jul. 6, 2011

(30) Foreign Application Priority Data
Oct. 29, 2010 (KR) 10-2010-0106733

(51) Int. Cl. H01J 1/62

(52) U.S. Cl. 313/504

(57) ABSTRACT

An organic light emitting display device is disclosed. In certain embodiments, the display has improved quality and lower cost because the subpixels of the display are oriented to have their longer sides parallel to the longer sides of the display. With the orientation, during crystallization of the subpixels, laser radiation is projected across the display device in a direction parallel to the short sides of the display device. Accordingly, less expensive laser equipment producing a shorter beam width may be used.

### CROSS-REFERENCE TO RELATED APPLICATIONS

This application claims priority to and the benefit of Korean Patent Application No. 10-2010-0106733, filed on Oct. 29, 2010, in the Korean Intellectual Property Office, the entire content of which is incorporated herein by reference.

### BACKGROUND

1. Field

The disclosed technology relates to an organic light emitting display device, and more particularly, to and organic light emitting display device having reduced manufacturing costs as a result of perpendicular laser projection on a panel during crystallization and having improved uniformity of transistors because of projecting the laser radiation to transistors simultaneously.

2. Description of the Related Technology

Recently, various flat panel displays (FPDs) having reduced weight and volume as compared to cathode ray tubes (CRT) have been developed. The FPDs include liquid crystal displays (LCD), field emission displays (FED), plasma display panels (PDP), and organic light emitting display devices.

An organic light emitting display device displays an image using organic light emitting diodes (OLED) that generate light through the re-combination of electrons and holes. The organic light emitting display has advantages of a high response speed and of being driven with low power consumption.

An organic light emitting display device includes pixels arranged in a matrix. Each of the pixels includes an R (Red)-subpixel for emitting red light, a G (Green)-subpixel for emitting green light, and a B (Blue)-subpixel for emitting blue light. Each of the R-, G-, and B-subpixels emits light according to a current supplied to an organic light emitting diode in response to a data signal. To this end, each of the R-, G-, and B-subpixels includes a plurality of transistors.

Each of the transistors, in general, includes a semiconductor layer, a gate electrode, a source electrode, and a drain electrode respectively having a source region, a drain region, and a channel region. The semiconductor layer is made of polycrystalline silicon (Poly-Si) or amorphous silicon (a-Si). Today, polycrystalline silicon having high electron mobility is used as the semiconductor layer in most organic light emitting display devices.

The polycrystalline silicon is generated by forming amorphous silicon on a substrate and crystallizing the amorphous silicon. Various methods of crystallizing the amorphous silicon may be used. In the most processes, excimer layer annealing (ELA) is used. In the ELA process, laser radiation is projected such that amorphous silicon is crystallized into polycrystalline silicon.

The process of projecting laser radiation to crystallize amorphous silicon into polycrystalline silicon has a significant influence on characteristics such as mobility and threshold voltages of the transistors. Therefore, the laser radiation must be projected to the transistors uniformly.

FIGS. 1 and 2 are views illustrating an existing panel and a crystallizing process thereof.

Referring to FIG. 1, a panel 10 is manufactured to have a long side portion 4 and a short side portion 6. The panel 10 includes pixels 2 arranged in the form of matrix. Here, each of the pixels 2 includes R-, G-, and B-subpixels arranged to have a stripe structure. In other words, each of the subpixels has a rectangular structure in which a side parallel to the short side portion 6 of the panel 10 is defined as a long side and a side parallel to the long side portion 4 is defined a short side.

In the process of forming panel 10, an ELA crystallizing equipment crystallizes transistors included in the respective pixels 2 by projecting laser radiation 30 in the horizontal direction parallel to the long side portion 4 of the panel 10.

However, when the laser radiation 30 is projected in the horizontal direction of the panel 10, the width of the laser beam is dependent on the size of the panel. For example, in a panel of about 55 inches, the long side portion 4 is about 1,200 mm and ELA crystallizing equipment for projecting laser radiation of about 1,500 mm is required. Such equipment is very expensive.

In order to use less expensive ELA crystallizing equipment, as illustrated in FIG. 2, laser radiation can be projected on half of the panel 20. For example, the panel 20 is divided into a right section and a left section, and laser radiation is separately projected to the right section and the left section respectively to crystallize transistors. However, when laser radiation is projected on to the panel 200 twice, laser radiation is projected on to a boundary 22 twice. In this case, characteristics of transistors positioned in the boundary 22 are different from those of transistors positioned outside the boundary 22, and as a result, stripe noise is generated at the boundary 22.

### SUMMARY OF CERTAIN INVENTIVE ASPECTS

One inventive aspect is an organic light emitting display device. The display device includes a display panel which has pixels connected to scan lines and data lines, an upper side, a lower side, a right side, and a left side, where the upper and lower sides are longer than the right and left sides. The display device also includes a scan driver configured to supply scan signals to the scan lines, and a data driver configured to supply data signals to the data lines, where each of the pixels includes R-, G-, and B-subpixels arranged in the vertical direction, and where each of the subpixels includes upper and lower sides which are longer than right and left sides, such that the right and left sides of the subpixels are substantially parallel to the right and left sides of the display panel.

### BRIEF DESCRIPTION OF THE DRAWINGS

The accompanying drawings, together with the specification, illustrate exemplary embodiments, and, together with the description, serve to explain various aspects and principles.

FIGS. 1 and 2 are panel views illustrating an existing panel and a crystallizing process thereof;

FIG. 3 is a block diagram illustrating an organic light emitting display device according to an embodiment of the present invention;

FIG. 4 is a schematic view illustrating a pixel according to an embodiment and subpixels thereof;

FIG. 5 is a panel view illustrating a panel according to an embodiment; and

FIG. 6 is a panel view illustrating a crystallizing process of the panel in FIG. 5.

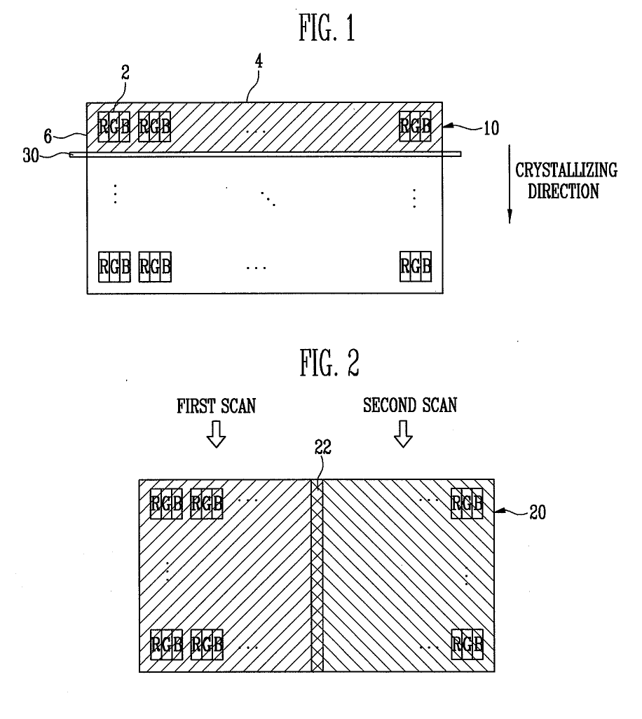

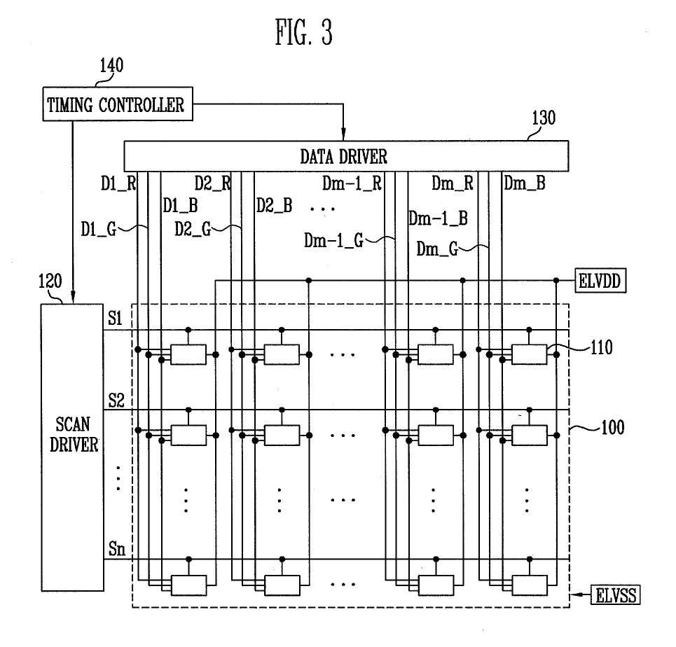

### DETAILED DESCRIPTION OF CERTAIN INVENTIVE EMBODIMENTS

Various aspects of exemplary embodiments are described in the following description and illustrated in the accompanying drawings.

Certain exemplary embodiments are described with reference to the accompanying drawings. When a first element is described as being coupled to a second element, the first element may be not only directly coupled to the second element but may be indirectly coupled to the second element via a third element. Further, some of the elements that are not essential to the complete understanding of the invention are omitted for clarity. Also, like reference numerals generally refer to like elements throughout.

Hereinafter, certain embodiments are described in detail with reference to FIGS. 3 to 6.

FIG. 3 is a block diagram illustrating an organic light emitting display device according to an embodiment.

Referring to FIG. 3, an organic light emitting display device according to some embodiments includes a display panel 100 having pixels 110 that are connected to scan lines S1 to Sn and data lines D1_R to Dm_B, a scan driver 120 for providing a scan signal to the respective pixels 110 through the scan lines S1 to Sn, and a data driver 130 for providing a data signal to the pixels 110 through the data lines D1_R to Dm_B. The organic light emitting display device may further include a timing controller 140 for controlling the scan driver 120 and the data driver 130.

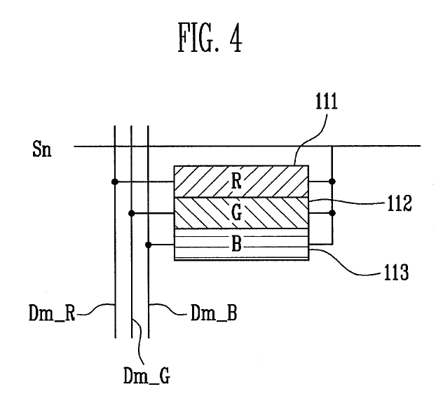

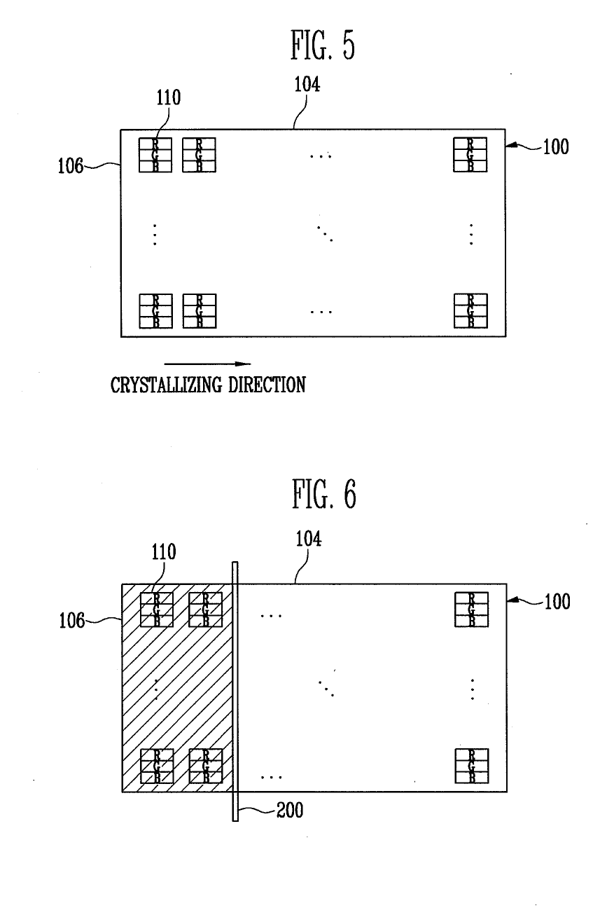

FIG. 4 is a schematic view illustrating a pixel according to some embodiments and subpixels thereof. FIG. 5 is a panel view illustrating a panel according to some embodiments.

The display panel 100 is a landscape type panel for displaying an image in landscape direction and includes a plurality of pixels 110 connected to the scan lines S1 to Sn and the data lines D1_R to Dm_B.

The display panel 100 has a rectangular shape with long sides 104 such as an upper side and the lower side and short sides 106 such as a right side and a left side. In the landscape type display panel 100, the number of pixels arranged in the horizontal direction is greater than the number of pixels arranged in the vertical direction.

Referring to FIGS. 4 and 5, each of the pixels 110 includes three R-, G-, and B-subpixels 111, 112, and 113 wherein the respective R-, G-, and B-subpixels 111, 112, and 113 are arranged in the vertical direction and respective short sides of which are disposed to be parallel to the short sides 106 of the display panel 100. Therefore, long sides of the respective R-, G-, and B-subpixels 111, 112, and 113 are parallel to the long sides 104 of the display panel 100.

That is, the R-, G-, and B-subpixels 111, 112, and 113 are sequentially arranged in a horizontal stripe structure from the upper side to the lower side. Although the R-, G-, and B-subpixels 111, 112, and 113 are arranged in the order of R-subpixel 11, G-subpixel 112, and B-subpixel 113 in FIG. 5, the arrangement order may be changed.

As such, when the respective R-, G-, and B-subpixels 111, 112, and 113 are arranged in the horizontal stripe structure, laser radiation may be projected with a one-time scan process during the crystallizing process of the respective pixels.

FIG. 6 is a view illustrating a crystallizing process of the panel in FIG. 5. The crystallizing process is described with reference to FIG. 6. When the respective R-, G-, and B-subpixels 111, 112, and 113 are arranged in the horizontal stripe structure, as illustrated in FIG. 6, laser radiation 200 is projected parallel to the short sides 106 of the display panel during the crystallizing process (that is, the laser radiation 200 is projected in the vertical direction of the display panel 100.) In this case, the length of the projected laser radiation 200 is determined by length of the short sides 106 of the display panel 100 and manufacturing costs are reduced. For example, in a case of a 55 inch display panel, ELA equipment for projecting laser radiation of 690 mm is required and manufacturing costs are reduced. In addition, since transistors formed in the display panel 100 are crystallized during the one-time scanning process, image quality is improved.

The scan driver 120 generates scan signals under the control of the timing controller 140 and provides the generated scan signals to the scan lines S1 to Sn sequentially. Then, the pixels 110 are selected by a unit of a horizontal line.

The data driver 130 generates data signals under the controller the timing controller 140 and provides the generated data signals to the data lines D1_R to Dm_B. The data signals provided to the data lines D1_R to Dm_B are provided to the selected pixels 110 by the scan signals. Then, each of the pixels 110 stores a voltage corresponding to the data signal and emits light with brightness corresponding to the stored voltage.

The scan lines S1 to Sn are positioned in the horizontal direction and arranged parallel to the long sides 104 of the display panel 100 wherein a single scan line is disposed on a single row having the pixels 110.

The data lines D1_R to Dm_B are positioned in the vertical direction and arranged parallel to the short sides 106 of the display panel 100 wherein three data lines are disposed in a single row having the pixels 110.

The scan driver 120 may be disposed at a right or left side of the display panel 100 and the data driver 130 may be disposed at the upper or lower side of the display panel 100.

When the scan lines S1 to Sn are positioned in the vertical direction and the data lines D1_R to Dm_B are positioned in the horizontal direction, since the load is increased as the number of pixels connected to the respective data lines Dl_R to Dm_B is increased so that data charging time is lengthened and since a frame memory for converting data that is provided by a unit of the horizontal line is required, manufacturing costs are increased and a driving method becomes complicated. Therefore, in some embodiments, the scan lines S1 to Sn are arranged in the horizontal direction and the data lines D1_R to Dm_B are arranged in the vertical direction.

In addition, when the scan driver 120 is disposed at the upper or lower side of the display panel 100, since the scan lines S1 to Sn must be wired to pass through the right or left side of the display panel 100 in order to arrange the scan lines S1 to Sn, costs are increased and manufacturing process becomes complicated. This problem also occurs in the arrangement of the data driver 130. Therefore, in some embodiments, the scan driver 120 is disposed at the right or left side of the display panel 100 and the data driver 130 is disposed at the upper or lower side of the display panel 100.

Pixels 110 positioned at the intersections between the scan lines S1 to Sn and the data lines D1_R to Dm_B are connected to a single scan line and to tree data lines.

FIG. 4 shows a pixel connected to an nth scan line. Sn and three data lines Dm_R, Dm_G, and Dm_B. Referring to FIG. 4, the respective R-, G-, and B-subpixels 111, 112, and 113 are commonly connected to the nth scan line Sn and the three data lines Dm_R, Dm_G, and Dm-B, respectively.

Therefore, when a scan signal is supplied to the nth scan line Sn, a data signal is supplied to the respective R-, G-, and B-subpixels 111, 112, and 113 through the three data lines Dm_R, Dm_G, and Dm_B, and the respective R-, G-, and B-subpixels 111, 112, and 113 store voltages corresponding to the data signals and emit light of corresponding brightness.

The present invention has been described in connection with certain exemplary embodiments. It is to be understood that the invention is not limited to the disclosed embodiments, but, on the contrary, is intended to cover various modifications and equivalent arrangements.

What is claimed is:

1. An organic light emitting display device comprising:
a display panel, comprising:
pixels connected to scan lines and data lines,
an upper side,
a lower side,
a right side, and
a left side,
wherein the upper and lower sides are longer than the right and left sides;
a scan driver configured to supply scan signals to the scan lines; and
a data driver configured to supply data signals to the data lines,
wherein each of the pixels includes R-, G-, and B-subpixels arranged in the vertical direction, and wherein each of the subpixels includes upper and lower sides which are longer than right and left sides, such that the right and left sides of the subpixels are substantially parallel to the right and left sides of the display panel.

2. The organic light emitting display device as claimed in claim 1, wherein the scan lines are substantially parallel to the long sides of the display panel and the data lines are substantially parallel to the short sides of the display panel.

3. The organic light emitting display device as claimed in claim 2, wherein the scan driver is disposed at the right or left side of the display panel and the data driver is disposed at the upper or lower side of the display panel.

4. The organic light emitting display device as claimed in claim 2, wherein each of the pixels is connected to a single scan line and three data lines and R-, G-, and B-subpixels in each of the pixels are commonly connected to the single scan line and respectively connected to the three data lines.

5. The organic light emitting display device as claimed in claim 1, wherein transistors included in each of the R-, G-, and B-subpixels are formed with a crystallization process, and the crystallization process includes projecting laser radiation parallel to the short sides of the display panel.
